(19) United States
(12) Patent Application Publication
(10) Pub. No.: US 2017/0092588 A1
(43) Pub. Date: Mar. 30, 2017

(54) FILM FORMING METHOD, SEMICONDUCTOR DEVICE MANUFACTURING METHOD, AND SEMICONDUCTOR DEVICE

(71) Applicant: ZEON CORPORATION, Tokyo (JP)

(72) Inventors: Kotaro Miyatani, Nirasaki-shi (JP); Takuya Kurotori, Nirasaki-shi (JP); Kohei Kawamura, Nirasaki-shi (JP)

(73) Assignee: ZEON CORPORATION, Tokyo (JP)

(21) Appl. No.: 15/127,924

(22) PCT Filed: Mar. 9, 2015
(86) PCT No.: PCT/JP2015/056853

§ 371 Date: Sep. 21, 2016

(30) Foreign Application Priority Data
Mar. 31, 2014 (JP) 2014-072753

(51) Int. Cl. H01L 23/532; H01L 21/768; H01L 23/528

(52) U.S. Cl. CPC H01L 23/53233; H01L 23/528; H01L 21/76802; H01L 21/76883; H01L 21/7684

(57) ABSTRACT

A film forming method according to a first embodiment includes a formation step of forming wiring in a groove and/or a hole formed in an insulating film containing fluorine by using wiring metal containing a dopant for preventing intrusion of the fluorine from the insulating film. The film forming method according to a first embodiment further includes a step of performing heat treatment after the wiring is formed, whereby a high concentration portion containing the dopant in a concentration higher than inside the wiring is formed on an interface of the wiring.

### FIELD

Various aspects and embodiments of the present invention relate to a film forming method, a semiconductor device manufacturing method, and a semiconductor device.

### BACKGROUND

If a multilayer wiring structure for achieving high integration of a semiconductor device employs a dual damascene process for example, a trench for embedding wiring and a via hole for embedding an electrode for connecting wiring on a lower layer side and wiring on an upper layer side are initially formed in an interlayer insulating film on the lower layer side. Wiring metal is then embedded into the trench and the via hole to form a lower layer structure. Similar processing is then repeated to stack layers, whereby the multilayer wiring structure is formed. For example, copper is used as the wiring metal.

To reduce the effective permittivity of wiring used in a semiconductor device, use of an insulating film containing fluorine has recently been considered. For example, use of a fluorine-added carbon film (fluorocarbon film) is considered. The film is formed of a compound of carbon (C) with fluorine (F), and can provide a relative permittivity as low as 2.5 or less. There is a technique for arranging a wiring layer made of copper on a fluorine-added carbon film and forming a 20-nm-thick titanium layer between the fluorine-added carbon film and the wiring layer by use of a sputtering apparatus.

There is also a formation technique in which a Cu (Ti) alloy film is formed by sputtering, and heat treatment is performed at temperature of about 400° C. to 600° C. to cause Ti to react with a dielectric film, thereby forming a Ti compound layer on the interface.

### CITATION LIST

### Patent Literature

Patent Literature 1: Japanese Patent Application Laid-Open No. Hei. 11-330075 A

### Non-Patent Literature

Non Patent Literature 1: Kohama, Kazuyuki, “Reduction in resistance and improvement in reliability of Cu wiring for Si-ULSI devices”, Kyoto University, 2012-03-26

### SUMMARY

### Technical Problem

However, there is a problem that a semiconductor device using an insulating film containing fluorine cannot be appropriately manufactured. For example, the foregoing conventional technique to use the sputtering apparatus cannot achieve easy formation. For example, if copper is used as the wiring metal and the fluorocarbon film is formed directly on the copper, CuF is formed to increase the resistivity of Cu and also to cause peeling. If the fluorocarbon film is formed directly on the copper, fluorine desorbed from the surface layer of the fluorine-added carbon film is diffused into the copper wiring due to the heat treatment, thereby increasing the wiring resistance. If the fluorine-added carbon film is formed directly on the wiring metal such as Cu, the wiring metal can be eroded by fluorine in plasma.

In the foregoing formation technique, heat treatment is performed at a temperature of about 400° C. to 600° C. to form the Ti compound layer on the interface. It is difficult to apply such a formation technique to general processes for manufacturing a semiconductor device.

### Solution to Problem

The disclosed film forming method includes, in one embodiment, a formation step of forming wiring in a groove and/or a hole formed in an insulating film containing fluorine by using wiring metal containing a dopant for preventing intrusion of the fluorine from the insulating film, and a step of performing heat treatment after the wiring is formed, whereby a high concentration portion containing the dopant in a concentration higher than inside the wiring is formed on an interface of the wiring.

### Advantageous Effects of Invention

According to an aspect of the film forming method, a semiconductor device manufacturing method, and a semiconductor device disclosed, there is provided an effect of enabling appropriate manufacturing of a semiconductor device that uses an insulating film containing fluorine.

### BRIEF DESCRIPTION OF DRAWINGS

FIG. 1 is a flowchart showing an example of a processing flow of a film forming method according to a first embodiment.

FIG. 2A is a part of a sectional view of a wafer for explaining the example of the processing flow of the film forming method according to the first embodiment.

FIG. 2B is a part of a sectional view of the wafer for explaining the example of the processing flow of the film forming method according to the first embodiment.

FIG. 3 is a flowchart showing an example of a method for manufacturing a semiconductor device having a multilayer wiring structure by using the film forming method according to the first embodiment.

FIG. 4A is a part of a sectional view of a wafer for explaining the example of the method for manufacturing a semiconductor device having a multilayer wiring structure by using the film forming method according to the first embodiment.

FIG. 4B is a part of a sectional view of the wafer for explaining the example of the method for manufacturing a semiconductor device having a multilayer wiring structure by using the film forming method according to the first embodiment.

FIG. 4C is a part of a sectional view of the wafer for explaining the example of the method for manufacturing a semiconductor device having a multilayer wiring structure by using the film forming method according to the first embodiment.

FIG. 4D is a part of a sectional view of the wafer for explaining the example of the method for manufacturing a semiconductor device having a multilayer wiring structure by using the film forming method according to the first embodiment.

FIG. 4E is a part of a sectional view of the wafer for explaining the example of the method for manufacturing a semiconductor device having a multilayer wiring structure by using the film forming method according to the first embodiment.

FIG. 4F is a part of a sectional view of the wafer for explaining the example of the method for manufacturing a semiconductor device having a multilayer wiring structure by using the film forming method according to the first embodiment.

FIG. 4G is a part of a sectional view of the wafer for explaining the example of the method for manufacturing a semiconductor device having a multilayer wiring structure by using the film forming method according to the first embodiment.

FIG. 4H is a part of a sectional view of the wafer for explaining the example of the method for manufacturing a semiconductor device having a multilayer wiring structure by using the film forming method according to the first embodiment.

FIG. 5 is a diagram showing an example of a semiconductor manufacturing apparatus including an annealing apparatus and a film forming apparatus in the first embodiment.

FIG. 6 is a diagram showing an example of a configuration of the film forming apparatus in the first embodiment.

FIG. 7 is a plan view showing a part of a first gas supply unit in the first embodiment.

FIG. 8 is a perspective view showing an example of an antenna unit in the first embodiment.

### DESCRIPTION OF EMBODIMENTS

Embodiments of the film forming method, the semiconductor device manufacturing method, and the semiconductor device disclosed will be described in detail below with reference to the drawings. It should be noted that the disclosed invention is not limited by these embodiments. The embodiments may be combined as appropriate without causing inconsistency in processing steps.

### First Embodiment

A film forming method according to a first embodiment includes a formation step of forming wiring in a groove and/or a hole formed in an insulating film containing fluorine by using wiring metal containing a dopant for preventing intrusion of the fluorine from the insulating film, and a step of performing heat treatment after the wiring is formed, whereby a high concentration portion containing the dopant in a concentration higher than inside the wiring is formed on an interface of the wiring.

For example, in the film forming method according to the first embodiment, the formation step of forming the wiring includes a step of forming the groove and/or the hole in the insulating film, a step of depositing the wiring metal on a surface in which the groove and/or the hole is/are formed among surfaces of the insulating film, and a polishing step of performing polishing after the wiring metal is deposited.

For example, in the film forming method according to the first embodiment, the dopant contains at least any one of titanium and aluminum. For example, in the film forming method according to the first embodiment, the high concentration portion contains the dopant in an amount of 1% or more. For example, in the film forming method according to the first embodiment, the wiring metal is copper.

For example, the film forming method according to the first embodiment further includes a step of forming an insulating film containing fluorine on the surface in which the wiring is formed among the surfaces of the insulating film. For example, the film forming method according to the first embodiment farther includes a crystallization step of performing heat treatment for crystallizing the deposited metal after the wiring metal is deposited and before the polishing is performed.

For example, a semiconductor device manufacturing method according to the first embodiment includes a formation step of forming wiring in a groove and/or a hole formed in an insulating film containing fluorine by using wiring metal containing a dopant for preventing intrusion of the fluorine from the insulating film, and a step of performing heat treatment at a first temperature after the wiring is formed, whereby a high concentration portion containing the dopant in a concentration higher than inside the wiring is formed on an interface of the wiring.

For example, a semiconductor device according to the first embodiment includes an insulating film containing fluorine, a groove and/or a hole formed in the insulating film, and wiring formed in the groove and/or the hole by using wiring metal containing a dopant for preventing intrusion of the fluorine from the insulating film, in which the wiring has, on an interface, a high concentration portion containing the dopant in a concentration higher than inside the wiring due to heat treatment performed at a first temperature.

(Film Forming Method According to First Embodiment)

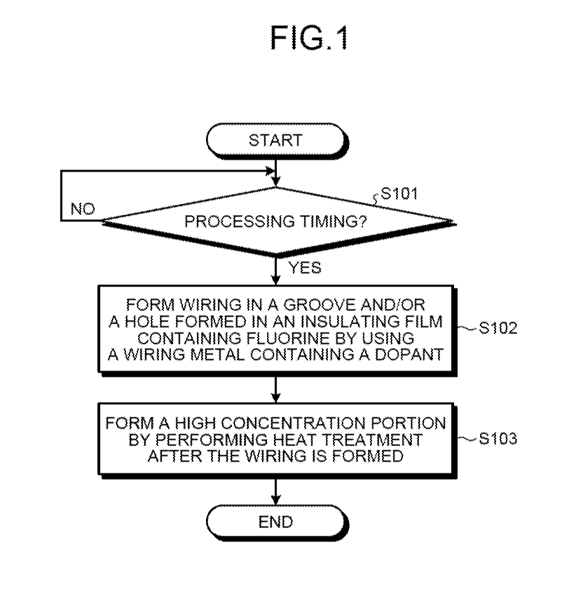

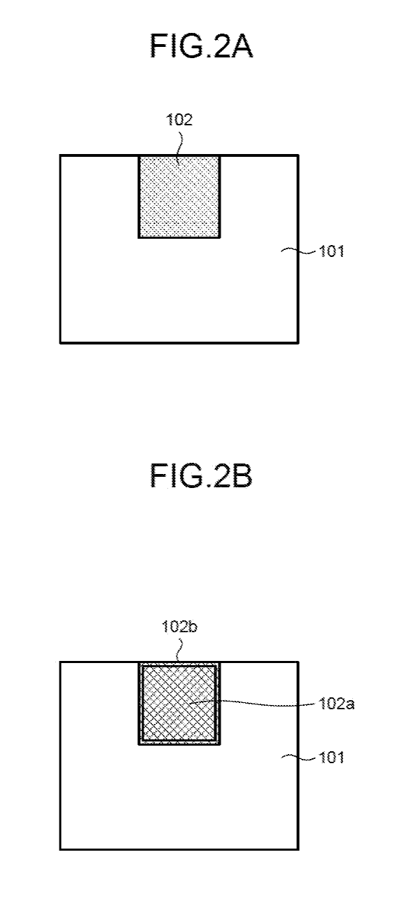

FIG. 1 is a flowchart showing an example of a processing flow of the film forming method according to the first embodiment. FIGS. 2A and 2B each are a part of a sectional view of a wafer for explaining the example of the processing flow of the film forming method according to the first embodiment.

As shown in FIG. 1, in the film forming method according to the first embodiment, when a timing for processing comes (yes in step S101), wiring is formed in a groove and/or a hole formed in an insulating film containing fluorine by using the wiring metal containing the dopant for preventing the intrusion of the fluorine from the insulating film as shown in FIG. 2A (step S102). As a result, wiring 102 is formed in an insulating film

Examples of the insulating film containing fluorine may include a fluorine-added carbon film. Any technique may be used to form the wiring in the groove and/or the hole formed in the fluorocarbon film. For example, PVD (Physical Vapor Deposition) may be used, or the wiring may be formed by plating. Alternatively, the metal deposited by using a film forming apparatus may be polished by CMP (Chemical Mechanical Polishing) to form the wiring.

Examples of the wiring metal may include copper. The dopant contains at least any one of titanium and aluminum.

The percentage of the dopant added to the wiring metal will be further described. The dopant may be added to the wiring metal to a degree sufficient to form the high concentration portion described below on the interface of the wiring by the heat treatment described below. For example, if the dopant is Ti, it is added to the wiring metal within a range of less than or equal to 1.1 atomic %. The percentage of the dopant metal may preferably be 0.5 to 1.1 atomic %, and more preferably 0.5 atomic %.

Returning to the description of FIG. 1, in the film forming method according to the first embodiment, the heat treatment is performed after formation of the wiring 102, whereby a high concentration portion 102b containing the dopant in a concentration higher than in an inside 102a of the wiring is formed on the interface of the wiring 102 as shown in FIG. 2B (step S103). For example, the heat treatment is executed by placing the base material in a chamber of an annealing apparatus and heating the base material while passing nitrogen. The heat treatment gas may be an inactive gas such as argon, or hydrogen. Note that, the heat treatment is not limited thereto. Any condition may be used as long as the high concentration portion can be formed.

For example, the high concentration portion 102b contains the dopant in an amount of 1% or more. If the dopant contained in the high concentration portion is Ti, the dopant is preferably less than or equal to 5 atomic %, and more preferably 2 atomic %.

For example, the wafer on which the wiring 102 has been formed is placed in an annealing apparatus and heated for the heat treatment. The heat treatment is preferably performed at a temperature lower than or equal to 350° C., and more preferably lower than or equal to 300° C. The heating time is preferably within 15 minutes, and more preferably within 5 minutes.

(Method for Manufacturing Semiconductor Device Having Multilayer Wiring Structure by Using Film Forming Method According to First Embodiment)

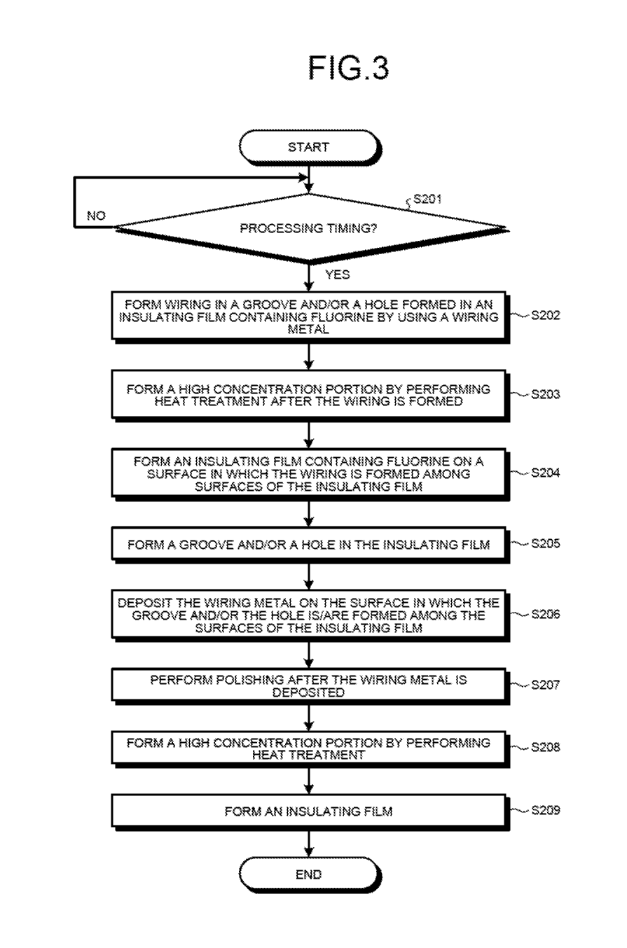

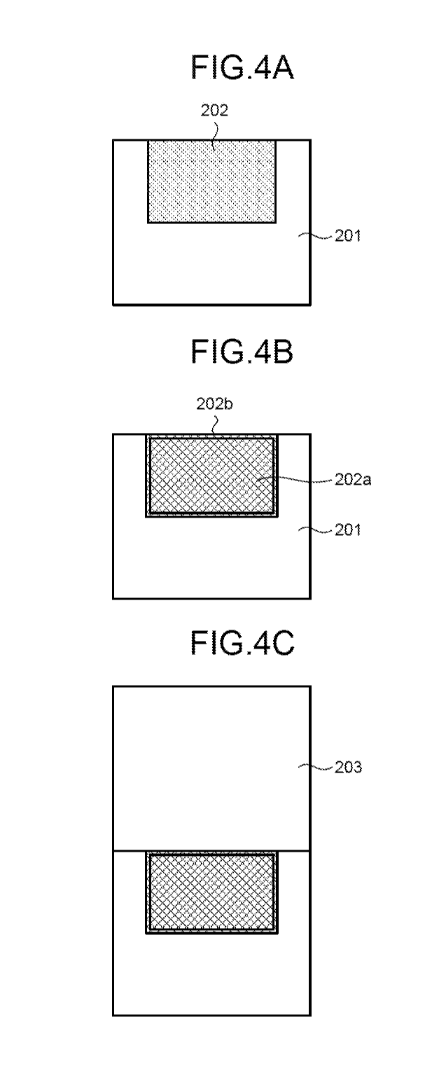

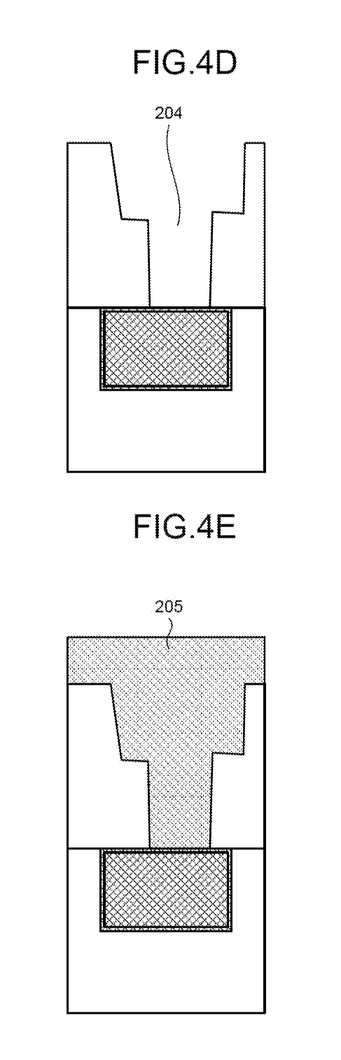

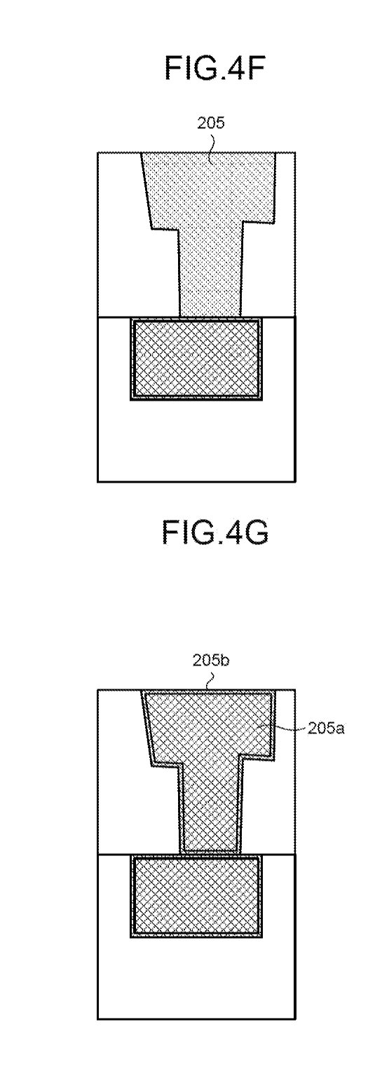

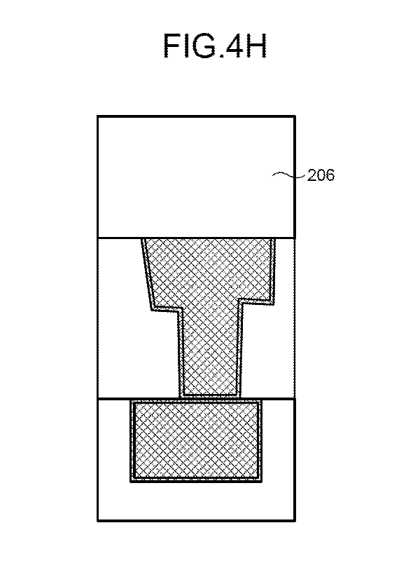

FIG. 3 is a flowchart showing an example of a method for manufacturing a semiconductor device having a multilayer wiring structure by using the film forming method according to the first embodiment. FIGS. 4A to 4H each are a part of a sectional view of a wafer for describing the example of the method for manufacturing a semiconductor device having a multilayer wiring structure by using the film forming method according to the first embodiment.

In the example shown in FIG. 3, the method for manufacturing a semiconductor device having a multilayer wiring structure will be described among methods for manufacturing a semiconductor device according to the first embodiment. The methods for manufacturing a semiconductor device according to the first embodiment are not limited thereto, and may be any manufacturing method including the foregoing film forming technique. For example, the methods may be applied to a method for manufacturing a semiconductor device having no multilayer wiring structure.

The following description will be given by using an example where copper is used as the wiring metal and titanium is used as the dopant. However, the present invention is not limited to this example. Appropriate combinations may be made without causing inconsistency in the processing steps.

As shown in FIG. 3, when a timing for processing comes (yes in step S201), wiring 202 is formed by using the wiring metal in a groove and/or a hole formed in an insulating film 201 containing fluorine as shown in FIG. 4A (step S202). For example, the wiring is formed by PVD or plating. Heat treatment is then performed after the formation of the wiring 202, whereby a high concentration portion 202b containing the dopant in a concentration higher than in an inside 202a of the wiring is formed on the interface of the wiring 202 as shown in FIG. 4B (step S203).

Later, as shown in FIG. 4C, an insulating film 203 containing fluorine is formed on the surface in which the wiring 202 is formed among the surfaces of the insulating film 201 (step S204). For example, the insulating film 203 containing fluorine is formed by placing the insulating film 201 in a film forming apparatus and supplying thereto a C5F8 gas as treatment gas and activating the gas, or equivalently, performing plasma treatment to form and deposit active species. The technique for forming an insulating film containing fluorine is not limited thereto, and any technique may be used.

Later, as shown in FIG. 4D, a groove and/or a hole 204 is/are formed in the insulating film 203 by using a certain technique (step S205). For example, a via trench is formed by performing plasma treatment in a film forming apparatus, followed by etching. Although not shown in FIG. 3 or 4D, for example, the via trench may be formed by forming a photoresist on the surface of the insulating film 204, followed by plasma treatment.

As shown in FIG. 4E, the wiring metal is formed on the surface in which the groove and/or the hole is/are formed among the surfaces of the insulating film 203 (step S206). Subsequently, as shown in FIG. 4F, polishing is performed after the deposition of the wiring metal, whereby the wiring metal deposited on portions other than the groove and/or the hole is removed (step S207). As a result, wiring 205 is formed in the insulating film 204. Examples of the polishing performed after the deposition of the wiring metal may include CMP (Chemical Mechanical Polishing).

Subsequently, as shown in FIG. 4G, heat treatment is performed after the formation of the wiring 205, whereby a high concentration portion 205b containing the dopant in a concentration higher than in an inside 205a of the wiring is formed on the interface of the wring 205 (step S208).

As shown in FIG. 4H, an insulating film 206 to make a wiring layer is then deposited (step S209) , The processing of the foregoing step S201 and the subsequent steps is repeated. As a result, a multilayer wiring structure is formed in which the wiring 202 formed in the insulating film 201 and the wiring formed in the insulating film 206 are connected with each other by the via trench formed in the insulating film 203. The processing is repeated to form a multilayer wiring structure having a predetermined number of layers.

The order of the foregoing processing procedures is not limited to the order described above, but it may be changed as appropriate without causing inconsistency in the processing steps. For example, in the foregoing processing procedure, the heat treatment is performed to form a high concentration portion at each formation of wiring. However, the present invention is not limited to this example. After formation of a plurality of pieces of wiring, high concentration portions may be formed in the plurality of pieces of wiring by one heat treatment.

(Film Forming Apparatus)

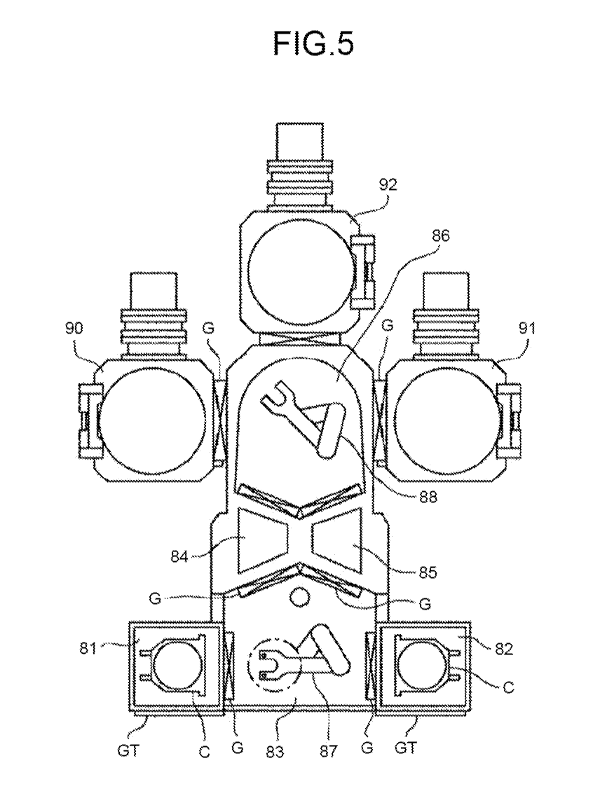

FIGS. 5 to 8 are diagrams showing an example of a semiconductor manufacturing apparatus used in the first embodiment. A description will be given below by using a case where the semiconductor manufacturing apparatus includes both a film forming apparatus and an annealing apparatus as an example. However, the present invention is not limited to this example, but the film forming apparatus and the annealing apparatus may be separate apparatuses.

FIG. 5 is a diagram showing an example of the semiconductor manufacturing apparatus including the annealing apparatus and the film forming apparatus in the first embodiment. In FIG. 5, the reference numerals 81 and 82 represent carrier chambers into which carriers C serving as wafer transfer containers are carried from the atmosphere side via gate doors GT. The reference numeral 83 represents a first transfer chamber, the reference numerals 84 and 85 represent preliminary vacuum chambers, and the reference numeral 86 represents a second transfer chamber. Such chambers have an airtight structure and are partitioned from the atmosphere side. The second transfer chamber 86 and the preliminary vacuum chambers 84 and 85 are in a vacuum atmosphere. The carrier chambers 81 and 82 and the first transfer chamber 83 may be put in an inactive gas atmosphere. The reference numeral 87 represents a first transfer unit, and the reference numeral 88 represents a second transfer unit. A film forming apparatus 90 for forming a fluorine-added carbon film serving as an interlayer insulating film, an annealing apparatus 91, and a film forming apparatus 92 are airtightly connected to the second transfer chamber 86.

In the semiconductor manufacturing apparatus of FIG. 5, a substrate in a carrier C is transferred, for example, by a route including the first transfer unit 87, the preliminary vacuum chamber 84 (or 85), the second transfer unit 88, and the film forming apparatus 90 in order. Then, for example, the formation of an insulating film containing fluorine, the formation of wiring, and the like are performed in the film forming apparatus 90. The substrate is also carried into the annealing device 91 via the second transfer unit 88, and heat treatment is executed. Subsequently, for example, the substrate is returned into the carrier C by the route reverse to the foregoing.

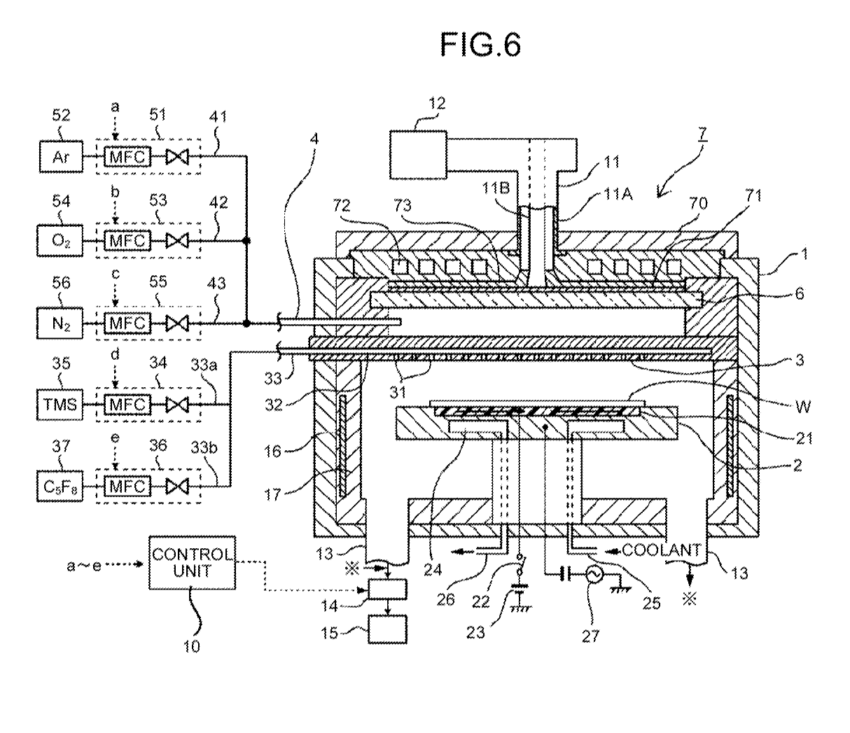

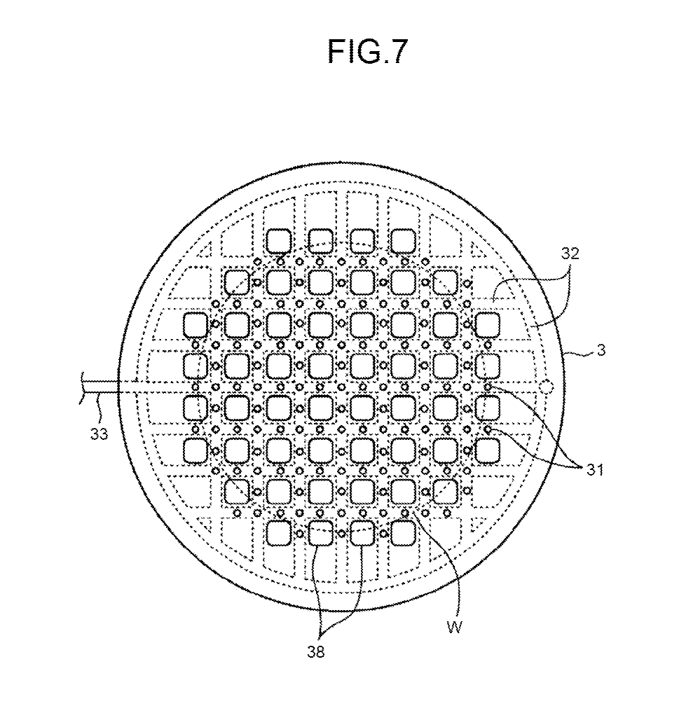

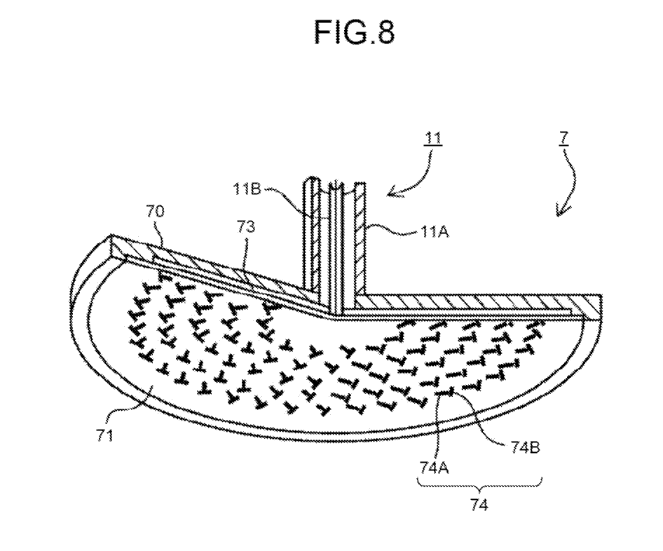

FIGS. 6 to 8 are diagrams showing an example of the film forming apparatus used in the first embodiment. The film forming apparatus shown in FIGS. 6 to 8 corresponds to the film forming apparatus 90 in FIG. 5. FIG. 6 is a diagram showing an example of a configuration of the film forming apparatus in the first embodiment. FIG. 7 is a plan view showing a part of a first gas supply unit in the first embodiment. FIG. 8 is a perspective view showing a part of an antenna unit in the first embodiment.

In FIG. 6, a processing container 1 is a processing container (vacuum chamber) made of aluminum, for example. A mounting table 2 made of, for example, aluminum nitride, aluminum oxide or the like is arranged in the processing container 1. An electrostatic chuck 21 is arranged in a surface portion of the mounting table 2. An electrode of the electrostatic chuck 21 is connected to a direct-current power supply 23 via a switch 22. A channel 24 for a temperature adjustment medium serving as a temperature adjustment unit is arranged inside the mounting table 2. A coolant serving as a temperature adjustment medium from an inlet 25 is passed through the channel 24 and discharged from an outlet 26. A semiconductor wafer (hereinafter, referred to as a wafer) W, which is a substrate on the mounting table 2, is maintained at a predetermined temperature by the temperature adjustment medium and a heater (not-shown). The mounting table 2 is connected to, for example, a 13.56-MHz bias high-frequency power supply 27.

A first gas supply unit 3 made of a conductor like aluminum is arranged above the mounting table 2. The first gas supply unit 3 is configured as a gas shower head having a substantially circular planar shape, for example. The first gas supply unit 3 has a large number of gas supply holes 31 formed in a surface opposed to the mounting table 2. For example, as shown in FIG. 7, grid-like gas channels 32 communicating with the gas supply holes 31 are formed in the first gas supply unit 3. The gas channels 32 are connected to a gas supply channel 33.

The gas supply channel 33 branches into branch pipes 33a and 33b at the proximal end. To the branch pipe 33a, a gas supply source 35 that is as a supply source of an organic silicon compound gas, such as vapor obtained by vaporizing trimethylsilane (SiH(CH3)3), is connected via a group of gas supply devices 34. To the other branch pipe 33b, a gas supply source 37 of a film formation gas as a treatment gas containing carbon and fluorine, such as a C₅F₈ gas, is connected via a group of gas supply devices 36. The groups of gas supply devices 34 and 36 include a valve and a mass flow controller serving as a flow rate adjustment unit.

The first gas supply unit 3 has a large number of openings 38 formed to run through the first gas supply unit 3 as shown in FIG. 7. The openings 38 are intended to pass through plasma into the space below the first gas supply unit 3. For example, the openings 38 are formed between adjacent gas channels 32.

A gas supply channel 4 constituting a gas supply channel serving as a second gas supply unit is arranged above the first gas supply unit 3. The gas supply channel 4 branches into branch pipes 41, 42, and 4 3 at the proximal end. The branch pipe 41 is connected with a group of gas supply devices 51 and a gas supply source 52 of a rare gas such as Ar (argon). The branch pipe 42 is connected with a group of gas supply devices 53 and a gas supply source 54 of O₂ (oxygen) gas. The branch pipe 43 is connected with a group of gas supply devices 55 and a gas supply source of N₂ (nitrogen) gas. The groups of gas supply devices 51, 53, and 55 include a valve and a mass flow controller that serves as a flow rate adjustment unit.

The gas supply technique is not limited to the foregoing example. For example, the first gas supply unit 3 may include gas supply channels of two systems. The group of gas supply holes 31 may be divided into gas supply holes allocated as an outlet of gas supply channels of one of the systems and the other gas supply holes allocated as an outlet of gas supply channels of the other system. The oxygen gas and the nitrogen gas may be supplied into the processing container 1 through the gas supply channels of one of the systems. The C5F8 gas and the trimethylsilane gas may be supplied into the processing container 1 through gas supply channels of the other system. The gas supply channels of the two systems are configured so that the gases flowing therethrough do not get mixed with each other. The gas supply holes of one of the systems and the gas supply holes of the other system are arranged in a matrix, i.e., alternately for example. By supplying the treatment gases in this manner, high in-plane uniformity can be achieved for the film quality and thickness of the film formed on the wafer W.

A plate (microwave transparent window) 6 made of a dielectric, such as alumina and quartz, is arranged above the first gas supply unit 3. An antenna unit 7 is arranged above the dielectric plate 6, in close contact with the dielectric plate 6. As also shown in FIG. 8, the antenna unit 7 includes a flat antenna main body 70 having a circular planar shape, and a disc-shaped planar antenna member (slot plate) 71 arranged on the bottom side of the antenna main body 70 and in which a large number of slots are formed. The antenna main body 70 and the planar antenna member 71 are made of a conductor. The antenna main body 70 and the planar antenna member 71 constitute a flat hollow circular waveguide, and are connected to a coaxial waveguide 11. In this example, the antenna main body 70 is configured to be divided into two members. A coolant reservoir 72 in which a coolant circulates via a coolant channel (not-shown) from outside is formed inside the antenna main body 70.

For example, a wave retardation plate 73 made of a low-loss dielectric material, such as alumina, silicon oxide, and silicon nitride, is arranged between the planar antenna member 71 and the antenna main body 70. The wave retardation plate 73 is intended to shorten microwave wavelengths to reduce the guide wavelength in the circular waveguide. The antenna main body 70, the planar antenna member 71, and the wave retardation plate 73 constitute a radial line slot antenna.

The antenna unit 7 having such a configuration is attached to the processing container 1 via a seal member (not-shown) so that the planer antenna member 71 is in close contact with the dielectric plate 6. The antenna unit 7 is connected to an external microwave generation unit 12 via the coaxial waveguide 11, and for example, microwaves having a frequency of 2.45 GHz or 8.4 GHz are supplied to the antenna unit 7. An outer waveguide 11A of the coaxial waveguide 11 is connected to the antenna main body 70. A center conductor 11B is connected to the planer antenna member 71 through an opening formed in the wave retardation plate 73.

For example, the planer antenna member 71 is made of a copper plate having a thickness of approximately 1 mm. As shown in FIG. 8, for example, a large number of slots 74 for generating circularly polarized waves are formed in the planer antenna member 71. The slots 74, each including a pair of slots 74A. and 74B arranged in a substantially T shape with a slight gap therebetween, are formed for example concentrically or spirally along the circumferential direction. The slots 74 may be arranged in a substantially V shape with a slight gap therebetween. Since the slots 74A and 74B are arranged to be generally orthogonal to each other, circularly-polarized waves including two orthogonal polarized components are radiated. Here, the pairs of slots 74A and 74B are arranged at. intervals corresponding to the wavelength of the microwaves compressed by the wave retardation plate 73, so that the microwaves are radiated as substantially plane waves from the planar antenna member 71.

Exhaust pipes 13 are connected to the bottom of the processing container 1. A vacuum pump 15 serving as an evacuation unit is connected to the proximal end of the exhaust pipes 13, for example, via a pressure adjustment unit 14 including a butterfly valve. A surrounding member (wall portion) 17 equipped with a heater 16 serving as a heating unit is arranged on the inner surface side of the inner wall of the processing container 1.

For example, the film formation apparatus 90 includes a control unit 10 including a computer. The control unit 10 controls the groups of gas supply devices 34, 36, 51, 53, and 55, the pressure adjustment unit 14, the heater 16, the microwave generation unit 12, the switch 22 of the electrostatic chuck 21 of the mounting table 2, and the like. More specifically, the film formation apparatus 90 includes a storage unit storing sequence programs for executing the steps of the foregoing film formation processing, and a unit for reading commands of the programs and outputting control signals to various units.

Next, the annealing apparatus 91 will be described further. For example, an apparatus having the same configuration as that of the film forming apparatus 90 is used for the annealing apparatus 91. A supply source of N2 gas is connected to the first gas supply channel. In this annealing apparatus 91, for example, a substrate on which a fluorine-added carbon film has been formed is carried into the processing container. Argon or N2 gas is supplied into the processing container from the first gas supply unit at a predetermined flow rate of, for example, 10 to 1000 sccm. At the same time, the interior of the processing container is maintained, for example, at a process pressure of 33.3 to 666.7 Pa (250 to 5000 mTorr) and heated for heat treatment.

### Effect of First Embodiment

As described above, the film forming method according to the first, embodiment includes the formation step of forming wiring in a groove and/or a hole formed in an insulating film containing fluorine by using wiring metal containing a dopant for preventing intrusion of the fluorine from the insulating film, and the step of performing heat treatment after the wiring is formed, whereby a high concentration portion containing the dopant, in a concentration higher than inside the wiring is formed on the interface of the wiring. This enables appropriate manufacturing of a semiconductor device by using the insulating film containing fluorine.

For example, in the film forming method according to the first embodiment, a high concentration layer can be formed only by performing heat treatment. This can lower the concentration of the dopant inside the wiring to easily reduce the resistivity, can prevent the peeling of the fluorocarbon film from the wiring, and can prevent the diffusion of fluorine contained in the insulating film into the inside of the wiring. As a result, the wiring can be appropriately formed.

Since wiring made of copper and the like is directly formed in the insulating film containing fluorine and then the high concentration layer is formed by the heat treatment, a semiconductor device can be manufactured by simple manufacturing steps.

For example, in the film forming method according to the first embodiment, the formation step of forming the wiring includes the step of forming the groove and/or the hole in the insulating film, the step of depositing the wiring metal on the surface in which the groove and/or the hole is/are formed among the surfaces of the insulating film, and the polishing step of performing polishing after the wiring metal is deposited. This enables appropriate formation of the wiring.

For example, in the film, forming method according to the first embodiment, the dopant contains at least any one of titanium and aluminum. As a result, the effect of the adjoining of the insulating film containing fluorine to the wiring can be prevented. For example, in the film forming method according to the first embodiment, the high concentration portion contains the dopant in an amount of 1% or more. This can prevent the diffusion of the fluorine from the insulating film containing fluorine to the wiring. For example, in the film forming method according to the first embodiment, the wiring metal is copper. As a result, appropriate wiring can be formed.

For example, the film forming method according to the first embodiment, further includes the step of forming an insulating film containing fluorine on the surface in which the wiring is formed among the surfaces of the insulating film. As a result, a multilayer wiring structure can be formed. For example, the film forming method according to the first embodiment further includes the crystallization step of performing heat treatment for crystallizing the deposited metal after the wiring metal is deposited and before the polishing is performed. As a result, the wiring can be compactly formed in the groove and/or the hole formed in the insulating film.

For example, the semiconductor device manufacturing method according to the first embodiment, includes the formation step of forming wiring in a groove and/or a hole formed in an insulating film containing fluorine by using wiring metal containing a dopant, for preventing intrusion of the fluorine from the insulating film, and the step of performing heat treatment at a first temperature after the wiring is formed, whereby a high concentration portion containing the dopant in a concentration higher than inside the wiring is formed on the interface of the wiring. This enables appropriate manufacturing of a semiconductor device. For example, a semiconductor device in which an insulating film containing fluorine and copper wiring are formed to adjoin each other can be easily formed.

For example, the semiconductor device according to the first embodiment includes an insulating film containing fluorine, a groove and/or a hole formed in the insulating film, and wiring formed in the groove and/or the hole by using wiring metal containing a dopant for preventing intrusion of the fluorine from the insulating film, the wiring having a high concentration portion containing the dopant in a concentration higher than inside the wiring, the high concentration portion being formed on an interface of the wiring by performing heat treatment at a first temperature. As a result,, a semiconductor device in which an insulating film containing fluorine and copper wiring are formed to adjoin each other can be easily implemented.

### Reference Signs List

90 film forming apparatus

91 annealing apparatus

101 insulating film

102 wiring

102a inside

102b high concentration portion

201 insulating film

202 wiring

202a inside

202b high concentration portion

203 insulating film

204 insulating film

205 wiring

205a inside

205b high concentration portion

206 insulating film

1. A film forming method comprising:
a formation step of forming wiring in a groove and/or a hole formed in an insulating film containing fluorine by using wiring metal containing a dopant for preventing intrusion of the fluorine from the insulating film; and
a step of performing heat treatment after the wiring is formed, whereby a high concentration portion containing the dopant in a concentration higher than inside the wiring is formed on an interface of the wiring,

2. The film forming method according to claim 1, wherein the formation step of forming the wiring comprises:
a step of forming the groove and/or the hole in the insulating film;
a step of depositing the wiring metal on a surface in which the groove and/or the hole is/are formed among surfaces of the insulating film; and
a polishing step of performing polishing alter the wiling metal is deposited.

3. The film forming method according to claim 1, wherein the dopant contains at least any one of titanium and aluminum.

4. The film forming method according to claim 1, wherein the high concentration portion contains the dopant in an amount of 1% or more.

5. The film forming method according to claim 1, wherein the wiring metal is copper.

6. The film forming method according to claim 1, further comprising a step of forming an insulating film containing fluorine on the surface in which the wiring is formed among the surfaces of the insulating film.

7. The film forming method according to claim 1, further comprising a crystallization step of performing heat treatment for crystallizing the deposited metal after the wiring metal is deposited and before polishing is performed.

8. A semiconductor device manufacturing method comprising:
a formation step of forming wiring in a groove and/or a hole formed in an insulating film containing fluorine by using wiring metal containing a dopant for preventing intrusion of the fluorine from the insulating film; and
a step of performing heat treatment at a first temperature after the wiring is formed, whereby a high concentration portion containing the dopant in a concentration higher than inside the wiring is formed on an interface of the wiring.

9. A semiconductor device comprising:
an insulating film containing fluorine;
a groove and/or a hole formed in the insulating film; and
wiring formed in the groove and/or the hole by using wiring metal containing a dopant for preventing intrusion of the fluorine from the insulating film, the wiring having a high concentration portion containing the dopant in a concentration higher than inside the wiring, the high concentration portion being formed on an interface of the wiring by performing heat treatment at a first temperature.

10. The film forming method according to claim 2, wherein the dopant contains at least any one of titanium and aluminum.

11. The film forming method according to claim 2, wherein the high concentration portion contains the dopant in an amount of 1% or more.

12. The film forming method according to claim 2, wherein the wiring metal is copper.

13. The film forming method according to claim 2, further comprising a step of forming an insulating film containing fluorine on the surface in which the wiring is formed among the
surfaces of the insulating film.

14. The film forming method according to claim 2, further comprising a crystallization step of performing heat treatment for crystallizing the deposited metal after the wiring metal is deposited and before polishing is performed.
